(19) United States
(12) Patent Application Publication
(10) Pub. No.: US 2024/0405789 A1
(43) Pub. Date: Dec. 5, 2024

(54) RADIO FREQUENCY MODULE

(71) Applicant: Murata Manufacturing Co., Ltd., Nagaokakyo-shi (JP)

(72) Inventor: Yuki OHMAE, Nagaokakyo-shi (JP)

(73) Assignee: Murata Manufacturing Co., Ltd., Nagaokakyo-shi (JP)

(21) Appl. No.: 18/675,216

(22) Filed: May 28, 2024

(30) Foreign Application Priority Data
May 31, 2023 (JP) 2023-090125

(51) Int. Cl. H04B 1/00; H04B 1/04

(52) U.S. Cl. CPC H04B 1/0078; H04B 1/04; H04B 2001/0408

(57) ABSTRACT

A radio frequency module includes a module substrate, an integrated circuit including power amplifiers, a matching circuit, a balun including a primary coil connected between output ends of the power amplifiers and a secondary coil connected between the matching circuit and the ground, power supply terminals switchably connected to a connection portion of the primary coil, a switch circuit connected between each of the power supply terminals and the primary coil, and a power supply line connecting an output terminal of the switch circuit and the connection portion of the primary coil. In plan view of the module substrate, a first distance between the power supply line and the matching circuit along a Y direction is longer than a second distance between the power supply line and a point on an outer edge of the balun along the Y direction.

### CROSS-REFERENCE TO RELATED APPLICATION

The present application claims priority to Japanese Application No. JP2023-090125, filed in Japan on May 31, 2023, the contents of which is incorporated by reference in its entirety.

### BACKGROUND

### 1. Technical Field

The present disclosure relates to a radio frequency module.

### 2. Description of the Related Art

In Japanese Unexamined Patent Application Publication No. 2022-170224, a differential amplifier is used to amplify a radio frequency signal.

### SUMMARY

However, in the case where the configuration in which a power supply voltage to be supplied to the differential amplifier is switchable is employed with the above technique in the related art, noise easily enters a power supply line. In the case where such a power supply line is coupled to a matching circuit and noise leaks into the matching circuit, the characteristics of a radio frequency module may deteriorate.

The present disclosure provides a radio frequency module with which the deterioration of characteristics of the radio frequency module can be suppressed even in the case where the configuration in which a power supply voltage to be supplied to a differential amplifier is switchable is employed.

A radio frequency module according to an aspect of the present disclosure includes a module substrate, an integrated circuit that is disposed on the module substrate and includes a first power amplifier and a second power amplifier, a matching circuit disposed on the module substrate, a balun that is disposed in the module substrate and includes a primary coil connected between an output end of the first power amplifier and an output end of the second power amplifier and a secondary coil connected between the matching circuit and a ground, a first power supply terminal and a second power supply terminal that are disposed on the module substrate and are switchably connected to a connection portion between both end portions of the primary coil, a switch circuit that is disposed on the module substrate and is connected between each of the first power supply terminal and the second power supply terminal and the primary coil, and a power supply line that is disposed on the module substrate and electrically connects between the switch circuit and the connection portion of the primary coil. In plan view of the module substrate, a first distance between the power supply line and the matching circuit along a direction perpendicular to a predetermined direction is longer than a second distance between the power supply line and a predetermined point on an outer edge of the balun along the direction perpendicular to the predetermined direction. The direction perpendicular to the predetermined direction is parallel to a line segment connecting the both end portions of the primary coil. The predetermined point is a point on the outer edge of the balun farthest from a perpendicular bisector of the line segment.

A radio frequency module according to an aspect of the present disclosure includes a module substrate, an integrated circuit that is disposed on the module substrate and includes a first power amplifier and a second power amplifier, a matching circuit disposed on the module substrate, a balun that is disposed in the module substrate and includes a primary coil connected between an output end of the first power amplifier and an output end of the second power amplifier and a secondary coil connected between the matching circuit and a ground, a first power supply terminal and a second power supply terminal that are disposed on the module substrate and are switchably connected to a connection portion between both end portions of the primary coil, a switch circuit that is disposed on the module substrate and is connected between each of the first power supply terminal and the second power supply terminal and the primary coil, and a power supply line that is disposed on the module substrate and electrically connects between an output terminal of the switch circuit and the connection portion of the primary coil. The module substrate is divided into a first region, a second region, and a third region along a predetermined direction, and the second region is located between the first region and the third region. The predetermined direction is perpendicular to a line segment connecting the both end portions of the primary coil in plan view of the module substrate. The balun is disposed in the second region and is not disposed in the first region and the third region. The output terminal of the switch circuit is disposed in the second region or the third region. The matching circuit is disposed in the first region and is not disposed in the second region.

According to the present disclosure, the deterioration of characteristics of the radio frequency module can be suppressed even in the case where the configuration in which a power supply voltage to be supplied to a differential amplifier is switchable is employed.

### BRIEF DESCRIPTION OF THE DRAWINGS

FIG. 1 is a diagram illustrating the circuit configuration of a radio frequency module according to a first embodiment;

FIG. 2 is a plan view of the radio frequency module according to the first embodiment;

FIG. 3 is a plan view of the radio frequency module according to the first embodiment;

FIG. 4 is a wiring diagram of the radio frequency module according to the first embodiment;

FIG. 5 is an exploded perspective view of a balun according to the first embodiment;

FIG. 6 is a cross-sectional view of the radio frequency module according to the first embodiment;

FIG. 7 is a plan view of a radio frequency module according to a second embodiment;

FIG. 8 is a plan view of the radio frequency module according to the second embodiment;

FIG. 9 is a wiring diagram of the radio frequency module according to the second embodiment;

FIG. 10 is a plan view of a radio frequency module according to another embodiment;

FIG. 11 is a plan view of the radio frequency module according to another embodiment; and

FIG. 12 is a cross-sectional view of the radio frequency module according to another embodiment.

### DETAILED DESCRIPTION

Embodiments of the present disclosure will be described in detail below with reference to drawings. The embodiments to be described below each illustrate a comprehensive or concrete example. The numerical values, shapes, materials, constituent elements, arrangements of the constituent elements, the ways in which the constituent elements are connected, and so forth described in the following embodiments are merely examples and are not intended to limit the present disclosure.

The drawings are schematically illustrated with appropriate accentuation, omission, or proportion adjustment to depict the present disclosure and are not necessarily illustrated in an exact manner, and the shape, positional relationship, and proportion may be different from actual ones. In the drawings, configurations that are substantially the same as each other are denoted by the same symbol and repeated description thereof may be omitted or simplified.

In the drawings to be referred to below, the X axis and the Y axis are axes perpendicular to each other on a plane parallel to main surfaces of a module substrate. Specifically, in the case where the module substrate has a rectangular shape in plan view, the X axis is parallel to a first side of the module substrate and the Y axis is parallel to a second side of the module substrate which is perpendicular to the first side. The Z axis is perpendicular to the main surfaces of the module substrate, a positive Z axis direction indicates an upward direction, and a negative Z axis direction indicates a downward direction.

In the following description, the expression “connected” includes not only the case where a circuit element is directly connected to another circuit element by a connection terminal and/or a wiring conductor but also the case where a circuit element is electrically connected to another circuit element via still another circuit element. The expression “directly connected” means that a circuit element is directly connected to another circuit element by a connection terminal and/or a wiring conductor without still another circuit element. The expression “C is connected between A and B” means that one end of C is connected to A and the other end of C is connected to B and means that C is disposed in series on a path connecting A and B to each other. The “path connecting A and B to each other” means a path formed by a conductor that electrically connects A to B.

A “terminal” means a point where a conductor inside an element ends. In the case where the impedance of a conductor between elements is sufficiently low, a terminal is interpreted as being any point on the conductor between elements or the entire conductor, rather than just a single point.

The expression “a component is disposed at a substrate” includes the case where the component is disposed on the main surface of the substrate and the case where the component is disposed in the substrate. The expression “the component is disposed on the main surface of the substrate” includes not only the case where the component is disposed on the main surface in a state of being in contact with the main surface of the substrate but also the case where the component is disposed above the main surface without being in contact with the main surface (e.g., the case where the component is stacked on another component disposed in contact with the main surface). The expression “the component is disposed on the main surface of the substrate” may include the case where the component is disposed in a recess portion defined in the main surface. The expression “the component is disposed in the substrate” includes not only the case where the component is encapsulated in the module substrate but also the case where the component is disposed in its entirely between both main surfaces of the substrate but not covered in part by the substrate and the case where only a part of the component is disposed in the substrate.

The expression “A is disposed between B and C” means that at least one of a plurality of line segments each connecting any point inside B and any point inside C passes through A. A “distance between A and B” means the shortest distance between A and B. That is, the “distance between A and B” means the length of the shortest line segment of a plurality of line segments each connecting any point on the surface of A and any point on the surface of B.

A “plan view of a module substrate” means orthographically projecting and viewing an object onto the XY plane from the positive side of the Z axis. The expression “A overlaps B in plan view” means that the region of A orthographically projected onto the XY plane overlaps the region of B orthographically projected onto the XY plane. The expression “A is disposed between B and C” means that at least one of a plurality of line segments each connecting any point inside B and any point inside C passes through A.

Terms indicating a relationship between elements, such as “parallel” and “perpendicular,” terms indicating the shape of an element, such as “rectangle,” and numerical ranges do not only represent strict meanings, but also include substantially equivalent ranges, such as errors of about several percent.

### First Embodiment

A first embodiment will be described. A communication device 5 according to the present embodiment can be used to provide a wireless connection. For example, the communication device 5 can be installed in user equipment (UE) in a cellular network (also referred to as a mobile network), such as a cellular phone, a smartphone, a tablet computer, or a wearable device. In another example, the installation of the communication device 5 can establish wireless connections in an Internet of Things (IoT) sensor device, a medical/healthcare device, a vehicle, an unmanned aerial vehicle (UAV) (so-called drone), and an automated guided vehicle (AGV). In still another example, the installation of the communication device 5 can establish wireless connections at wireless access points or wireless hotspots.

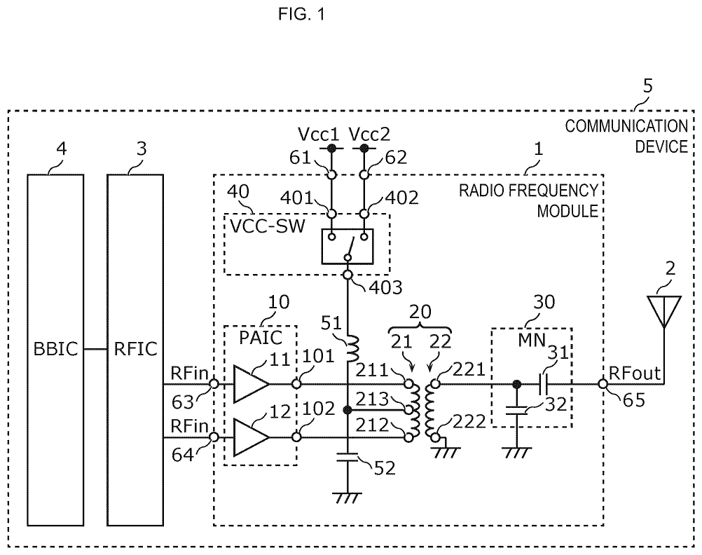

The circuit configuration of the communication device 5 according to the present embodiment and a radio frequency module 1 according to the present embodiment will be described with reference to FIG. 1. FIG. 1 is a diagram illustrating the circuit configuration of the communication device 5 according to the present embodiment.

The circuit configuration illustrated in FIG. 1 is an example, and the communication device 5 and the radio frequency module 1 can be installed using any of various circuit implementations and circuit techniques. Accordingly, the following description of the communication device 5 and the radio frequency module 1 should not be interpreted in a limited manner.

### 1.1 Circuit Configuration of Communication Device 5

The circuit configuration of the communication device 5 according to the present embodiment will be described with reference to FIG. 1. The communication device 5 is installed in UE and includes the radio frequency module 1, an antenna 2, a radio frequency integrated circuit (RFIC) 3, and a baseband integrated circuit (BBIC) 4.

The radio frequency module 1 can transmit a radio frequency signal between the antenna 2 and the RFIC 3. The circuit configuration of the radio frequency module 1 will be described below.

The antenna 2 is connected to an antenna connection terminal 65 of the radio frequency module 1. The antenna 2 can receive a radio frequency signal from the radio frequency module 1 and transmit the radio frequency signal to the outside of the communication device 5. The antenna 2 may receive a radio frequency signal from the outside of the communication device 5 and supply the radio frequency signal to the radio frequency module 1. The antenna 2 does not necessarily have to be included in the communication device 5. The communication device 5 may include one or more antennas in addition to the antenna 2.

The RFIC 3 is an example of a signal processing circuit for processing a radio frequency signal. Specifically, the RFIC 3 can perform signal processing, such as up-conversion, upon a transmission signal supplied from the BBIC 4 and output a radio frequency transmission signal generated as a result of the signal processing to the radio frequency module 1. The RFIC 3 may perform signal processing, such as down-conversion, upon a radio frequency reception signal received via the radio frequency module 1 and output a reception signal generated as a result of the signal processing to the BBIC 4. The RFIC 3 may include a control unit for controlling, for example, a switch and an amplifier included in the radio frequency module 1. The function of the controller of the RFIC 3 may be partially or entirely implemented outside the RFIC 3 and may be implemented in, for example, the BBIC 4 or the radio frequency module 1.

The BBIC 4 is a baseband signal processing circuit for performing signal processing using an intermediate frequency band lower than the frequency of a radio frequency signal transmitted by the radio frequency module 1. Examples of a signal processed by the BBIC 4 include an image signal for image display and/or an audio signal for conversation through a speaker. The BBIC 4 does not necessarily have to be included in the communication device 5.

### 1.2 Circuit Configuration of Radio Frequency Module 1

Next, the circuit configuration of the radio frequency module 1 according to the present embodiment will be described with reference to FIG. 1. The radio frequency module 1 includes power amplifiers 11 and 12, a balun 20, a matching circuit (matching network (MN)) 30, a switch circuit 40, an inductor 51, a capacitor 52, power supply terminals 61 and 62, radio frequency input terminals 63 and 64, and the antenna connection terminal 65.

The power amplifiers 11 and 12 are examples of a first power amplifier and a second power amplifier, respectively, and are included in an integrated circuit 10. An input end of the power amplifier 11 is connected to the radio frequency input terminal 63, and an output end of the power amplifier 11 is connected to an end portion 211 of a primary coil 21 in the balun 20 via an output terminal 101 of the integrated circuit 10. An input end of the power amplifier 12 is connected to the radio frequency input terminal 64, and an output end of the power amplifier 12 is connected to an end portion 212 of the primary coil 21 in the balun 20 via an output terminal 102 of the integrated circuit 10.

The power amplifiers 11 and 12 can form a differential amplifier. Specifically, the power amplifiers 11 and 12 can amplify a differential signal supplied from the RFIC 3 via the radio frequency input terminals 63 and 64 using a power supply voltage Vcc1 or Vcc2 supplied from a power supply circuit Ivia the power supply terminal 61 or 62.

The balun 20 may sometimes be called a transformer and can combine a differential signal (balanced signal) with a single-ended signal (unbalanced signal). A differential signal means two signals of 180° out of phase transmitted via different signal lines and may sometimes be called a balanced signal. A single-ended signal means a single signal transmitted via a single signal line and may sometimes be called an unbalanced signal. The balun 20 includes the primary coil 21 and a secondary coil 22.

The primary coil 21 is connected between the output end of the power amplifier 11 and the output end of the power amplifier 12. Specifically, the end portion 211 of the primary coil 21 is connected to the output end of the power amplifier 11 via the output terminal 101 of the integrated circuit 10. The end portion 212 of the primary coil 21 is connected to the output end of the power amplifier 12 via the output terminal 102 of the integrated circuit 10. A connection portion 213 between the end portions 211 and 212 of the primary coil 21 is switchably connected to the power supply terminals 61 and 62. The connection portion 213 may be located at the midpoint of the primary coil 21.

The secondary coil 22 is connected between the matching circuit 30 and the ground. Specifically, an end portion 221 of the secondary coil 22 is connected to the matching circuit 30, and an end portion 222 of the secondary coil 22 is connected to the ground.

The matching circuit 30 is connected between the balun 20 and the antenna connection terminal 65 and can perform impedance matching between the balun 20 and the antenna 2. The matching circuit 30 includes capacitors 31 and 32. The capacitor 31 is connected between the end portion 221 of the secondary coil 22 and the antenna connection terminal 65. The capacitor 32 is connected between a path between the secondary coil 22 and the capacitor 31 and the ground. The circuit configuration of the matching circuit 30 is not limited to the circuit configuration illustrated in FIG. 1. For example, the matching circuit 30 may include an inductor and does not necessarily have to include the capacitor 31 and/or the capacitor 32.

The switch circuit 40 is connected between each of the power supply terminals 61 and 62 and the primary coil 21 and can switch the connection of the primary coil 21 between the power supply terminals 61 and 62. Specifically, the switch circuit 40 includes an input terminal 401 connected to the power supply terminal 61, an input terminal 402 connected to the power supply terminal 62, and an output terminal 403 connected to the connection portion 213 of the primary coil 21 via the inductor 51. In this connection configuration, the switch circuit 40 can exclusively connect the output terminal 403 to the input terminals 401 and 402 in response to, for example, a control signal from the RFIC 3. The switch circuit 40 is formed by, for example, a single-pole double-throw (SPDT) switch circuit.

The inductor 51 is a so-called choke inductor and is connected between each of the power supply terminals 61 and 62 and the balun 20. Specifically, one end of the inductor 51 is switchably connected to the power supply terminal 61 and 62 via the switch circuit 40. The other end of the inductor 51 is connected to the connection portion 213 of the primary coil 21. The inductor 51 does not necessarily have to be included in the radio frequency module 1.

The capacitor 52 is a so-called bypass capacitor or decoupling capacitor and is connected between the ground and a path connecting between each of the power supply terminals 61 and 62 and the balun 20. Specifically, one end of the capacitor 52 is connected to a path connecting the connection portion 213 of the primary coil 21 and the other end of the inductor 51, and the other end of the capacitor 52 is connected to the ground. The capacitor 52 does not necessarily have to be included in the radio frequency module 1.

The power supply terminals 61 and 62 are external connection terminals of the radio frequency module 1, are connected to a power supply circuit outside the radio frequency module 1, and are connected to the input terminals 401 and 402 of the switch circuit 40, respectively in the radio frequency module 1.

The radio frequency input terminals 63 and 64 are external connection terminals of the radio frequency module 1, are connected to the RFIC 3 outside the radio frequency module 1, and are connected to the input ends of the power amplifiers 11 and 12, respectively in the radio frequency module 1. The radio frequency input terminals 63 and 64 can receive a differential signal from the RFIC 3. One of the radio frequency input terminals 63 and 64 may receive a single-ended signal from the RFIC 3. In this case, the radio frequency module 1 does not necessarily have to include the other one of the radio frequency input terminals 63 and 64 and may include a balun for converting a single-ended signal into a differential signal.

The antenna connection terminal 65 is an external connection terminal of the radio frequency module 1, is connected to the antenna 2 outside the radio frequency module 1, and is connected to the matching circuit 30 in the radio frequency module 1.

The circuit configuration of the radio frequency module illustrated in FIG. 1 is an example and is not limited thereto. For example, the radio frequency module 1 may further include a filter. In this case, for example, the filter may be connected between the matching circuit 30 and the antenna connection terminal 65.

### 1.3 Installation Example of Radio Frequency Module 1

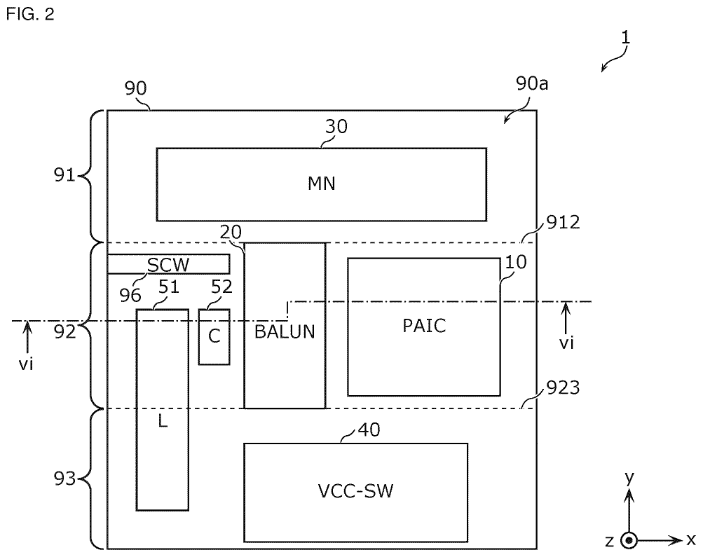

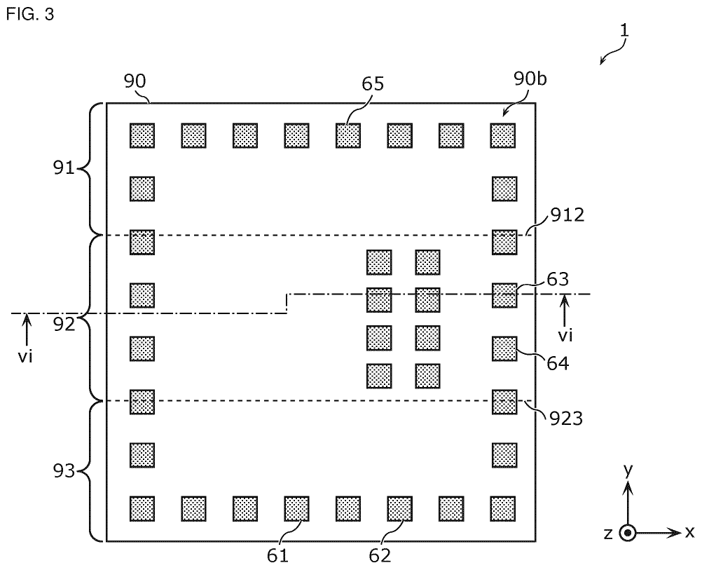

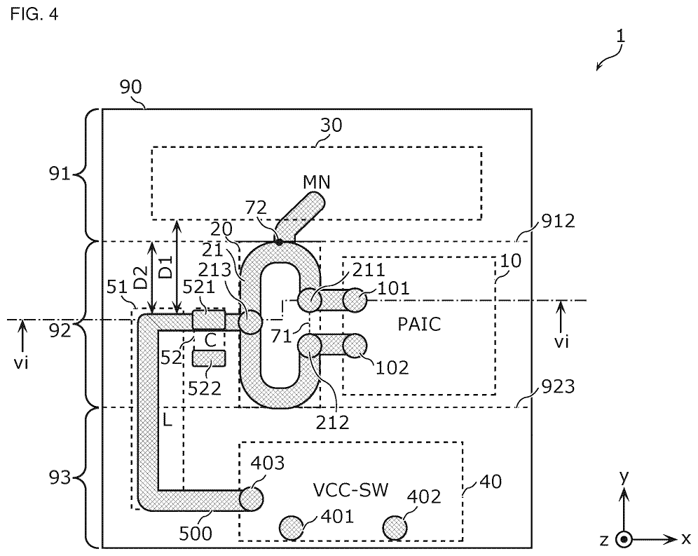

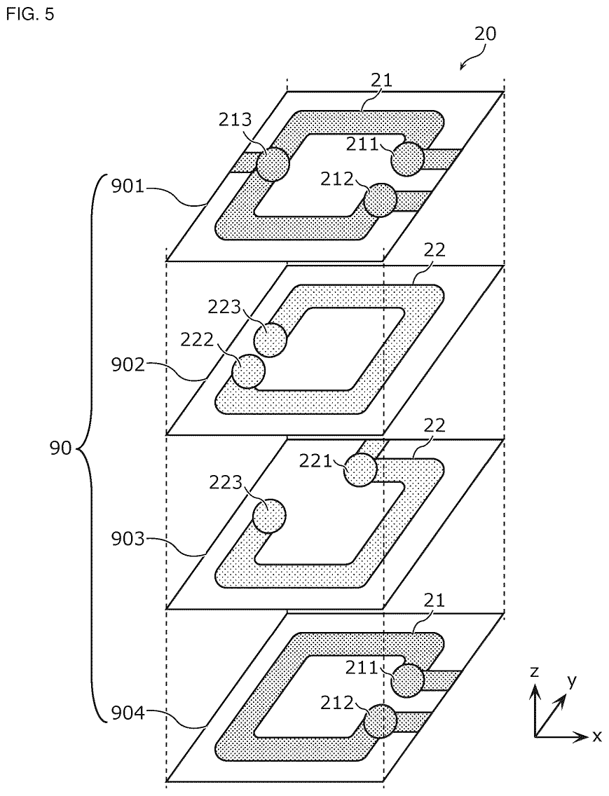

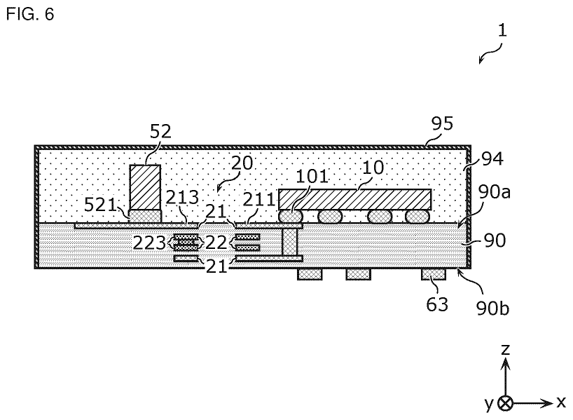

Next, the installation example of the radio frequency module 1 having the above circuit configuration will be described with reference to FIGS. 2 to 6. FIG. 2 is a plan view of the radio frequency module 1 according to the present embodiment. FIG. 3 is a plan view of the radio frequency module 1 according to the present embodiment, with a main surface 90b of a module substrate 90 viewed in perspective from the positive side of the Z axis. FIG. 4 is a wiring diagram of the radio frequency module 1 according to the present embodiment. FIG. 5 is an exploded perspective view of the balun 20 according to the present embodiment. FIG. 6 is a cross-sectional view of the radio frequency module 1 according to the present embodiment. The cross section of the radio frequency module 1 in FIG. 6 is taken along a line vi-vi in FIGS. 2 to 4.

In FIGS. 2 and 4, some of components are marked with labels (e.g., “MN”) representing the components so that the arrangement relationship of the components can be easily understood, but actual components do not necessarily have to be marked with such labels. In FIG. 2, the illustration of a resin member 94 covering a plurality of circuit components and a shield electrode layer 95 covering the surface of the resin member 94 is omitted.

FIGS. 2 to 6 illustrate an installation example of the radio frequency module 1, and the radio frequency module 1 can be installed using any of various installations and circuit techniques. Accordingly, the following description of the radio frequency module 1 should not be interpreted in a limited manner.

The module substrate 90 has a main surface 90a and the main surface 90b facing each other. The main surface 90a is an example of a first main surface and may sometimes be called a top surface or a front surface. The main surface 90b is an example of a second main surface and may sometimes be called a bottom surface or a back surface. Wiring lines and via conductors are formed in the module substrate 90 and on the main surfaces 90a and 90b.

The module substrate 90 is divided into regions 91 to 93 along an X direction. The X direction is an example of a predetermined direction and is perpendicular to a line segment 71 connecting the end portions 211 and 212 of the primary coil 21. Specifically, the module substrate 90 is divided into the regions 91 and 92 by a boundary line 912 extending in the X direction, and is divided into the regions 92 and 93 by a boundary line 923 extending in the X direction. The boundary lines 912 and 923 are virtual lines and do not necessarily have to be illustrated on the module substrate 90.

The line segment 71 connecting the end portions 211 and 212 of the primary coil 21 is the shortest of a plurality of line segments each connecting any point on the surface of the end portion 211 and any point on the surface of the end portion 212. That is, the line segment 71 connects the end portions 211 and 212 with the shortest distance.

The regions 91 to 93 are examples of a first region, a second region, and a third region, respectively and are rectangular in shape in plan view. The region 92 is located between the regions 91 and 93 in plan view. The shapes of the module substrate 90 and the regions 91 to 93 are rectangular in plan view in the present embodiment, but are not limited to rectangles.

Although, for example, a low temperature co-fired ceramic (LTCC) substrate or a high temperature co-fired ceramic (HTCC) substrate having a laminated structure of a plurality of dielectric layers, a component built-in substrate, a substrate including a redistribution layer (RDL), or a printed circuit board can be used as the module substrate 90, a substrate serving as the module substrate 90 is not limited thereto.

The integrated circuit 10 (PAIC) is disposed on the main surface 90a of the module substrate 90 and is disposed in the region 92 of the module substrate 90. The integrated circuit 10 may be disposed in the region 91 or 93.

The integrated circuit 10 includes hetero junction bipolar transistors (HBTs) forming the power amplifiers 11 and 12 and can be manufactured with a semiconductor material. As a semiconductor material for the integrated circuit 10, for example, silicon germanium (SiGe) or gallium arsenide (GaAs) can be used.

Amplification transistors forming the power amplifiers 11 and 12 are not limited to HBTs. For example, the power amplifier 11 and/or the power amplifier 12 may be formed by a high-electron-mobility transistor (HEMT) or a metal semiconductor field-effect transistor (MESFET). In this case, as a semiconductor material for the integrated circuit 10, gallium nitride (GaN) or silicon carbide (SiC) may be used.

The balun 20 (BALUN) is disposed in the module substrate 90 such that the winding axis of the balun 20 intersects the module substrate 90, orthogonally in the present embodiment. Specifically, the balun 20 is formed by a pattern wiring line in a plurality of layers 901 to 904 of the module substrate 90. The balun 20 is disposed in the region 92 of the module substrate 90 and is not disposed in the regions 91 and 93 of the module substrate 90. In the present embodiment, the balun 20 is disposed between the matching circuit 30 and the switch circuit 40.

The primary coil 21 is formed in the layers 901 and 904 as illustrated in FIG. 5. The end portions 211 and 212 of the primary coil 21 are disposed in the layers 901 and 904, and are electrically connected to the output terminals 101 and 102 of the integrated circuit 10, respectively. The connection portion 213 of the primary coil 21 is disposed in the layer 901 and is electrically connected to the output terminal 403 of the switch circuit 40 via a power supply line 500.

The secondary coil 22 is formed in the layers 902 and 903 as illustrated in FIG. 5. The end portion 221 of the secondary coil 22 is disposed in the layer 903 and is located farthest from the region 93 of the portions of the secondary coil 22. Conversely, the end portion 221 is nearest to the region 91 of the portions of secondary coil 22. The end portion 221 is electrically connected to the matching circuit 30. The connection portion 222 of the secondary coil 22 is disposed in the layer 902 and is electrically connected to the ground. Connection portions 223 disposed in the layers 902 and 903 are electrically connected to each other via a via conductor as illustrated in FIG. 6.

The matching circuit 30 (MN) is disposed on the main surface 90a of the module substrate 90. The matching circuit 30 is disposed in the region 91 of the module substrate 90 and is not disposed in the regions 92 and 93 of the module substrate 90. The capacitors 31 and 32 included in the matching circuit 30 are installed as chip capacitors. A chip capacitor means a surface-mount device (SMD) forming a capacitor. The installation of the capacitors 31 and 32 is not limited to a chip capacitor. For example, the capacitors 31 and 32 may be partially or entirely installed as an integrated passive device (IPD) or a pattern wiring line of the module substrate 90.

The switch circuit 40 (VCC-SW) is disposed on the main surface 90a of the module substrate 90. The switch circuit 40 is disposed in the region 93 of the module substrate 90 and is not disposed in the regions 91 and 92 of the module substrate 90. The input terminals 401 and 402 and the output terminal 403 of the switch circuit 40 are also disposed in the region 93 of the module substrate 90 and are not disposed in the regions 91 and 92 of the module substrate 90. As the switch circuit 40, a semiconductor integrated circuit including a field effect transistor (FET) can be used. In this case, for example, silicon (Si) is used as a semiconductor material. As the semiconductor material, GaAs, SiGe, GaN, or SiC may be used.

The inductor 51 is formed by the power supply line 500 electrically connecting between the switch circuit 40 and the balun 20. The inductor 51, that is, the power supply line 500, is disposed in the regions 92 and 93 of the module substrate 90 and is not disposed in the region 91 of the module substrate 90.

The capacitor 52 is disposed on the main surface 90a of the module substrate 90. The capacitor 52 is disposed in the region 92 of the module substrate 90 and is not disposed in the regions 91 and 93 of the module substrate 90. The capacitor 52 is connected between the power supply line 500 and the ground. Specifically, a terminal 521 of the capacitor 52 is connected to the power supply line 500, and a terminal 522 of the capacitor 52 is connected to the ground.

On the main surface 90b of the module substrate 90, a plurality of external connection terminals including the power supply terminals 61 and 62, the radio frequency input terminals 63 and 64, and the antenna connection terminal 65 are disposed. The multiple external connection terminals are formed by, for example, copper electrodes or solder electrodes and are electrically connected to, for example, an input/output terminal and/or a ground terminal on a mother board disposed in the negative Z-axis direction of the radio frequency module 1.

The power supply terminals 61 and 62 are disposed in the region 93 of the module substrate 90 and at least partly overlap the switch circuit 40 in plan view of the module substrate 90. The power supply terminals 61 and 62 are electrically connected to the input terminals 401 and 402 of the switch circuit 40, respectively via, for example, via conductors passing through the module substrate 90.

The radio frequency input terminals 63 and 64 are disposed in the region 92 of the module substrate 90 and at least partly overlaps the integrated circuit 10 in plan view of the module substrate 90. The radio frequency input terminals 63 and 64 are electrically connected to the input terminals of the integrated circuit 10 via, for example, via conductors electrically connecting between the layers of the module substrate 90.

The antenna connection terminal 65 is disposed in the region 91 of the module substrate 90. The antenna connection terminal 65 is electrically connected to the matching circuit 30 via, for example, a via conductor passing through the module substrate 90.

The resin member 94 covers the components disposed on the main surface 90a of the module substrate 90. The resin member 94 is made of, for example, an epoxy resin and has a function of ensuring reliability, such as mechanical strength and moisture resistance, of a plurality of electronic components on the main surface 90a. The resin member 94 does not necessarily have to be included in the radio frequency module 1.

The shield electrode layer 95 is a metal thin film formed by, for example, sputtering. The shield electrode layer 95 is formed to cover the surface (top surface and side surfaces) of the resin member 94. The shield electrode layer 95 is connected to the ground, suppresses entrance of external noise into the electronic components forming the radio frequency module 1, and suppresses interference with another module or another device due to noise generated in the radio frequency module 1. The shield electrode layer 95 does not necessarily have to be included in the radio frequency module 1.

A metal wall 96 (SCW) is a copper shield wall and is disposed between the matching circuit 30 and the switch circuit 40 on the main surface 90a of the module substrate 90. The metal wall 96 is erected toward the Z direction from the main surface 90a of the module substrate 90. The tip of the metal wall 96 may be joined to the shield electrode layer 95 and is connected to the ground.

The material for the metal wall 96 is not limited to copper. For example, the material for the metal wall 96 may be aluminum. The shape of the metal wall 96 is not limited to a plate. For example, the metal wall 96 may be formed of a plurality of post electrodes. A ground pattern electrode of the module substrate 90 may be disposed between the matching circuit 30 and the switch circuit 40 in addition to or instead of the metal wall 96. The metal wall 96 does not necessarily have to be included in the radio frequency module 1.

As illustrated in FIG. 4, a distance D1 (an example of a first distance) between the power supply line 500 and the matching circuit 30 along a Y direction is longer than a distance D2 (an example of a second distance) between the power supply line 500 and a point 72 on the outer edge of the balun 20 along the Y direction in plan view of the module substrate 90. The Y direction is an example of a direction perpendicular to the predetermined direction and is parallel to the line segment 71 connecting the end portions 211 and 212 of the primary coil 21. The point 72 is an example of a predetermined point and is a point on the outer edge of the balun 20 farthest from the perpendicular bisector of the line segment 71.

### 1.4 Effects, Etc.

As described above, the radio frequency module 1 according to the present embodiment includes the module substrate 90, the integrated circuit 10 that is disposed on the module substrate 90 and includes the power amplifiers 11 and 12, the matching circuit 30 disposed on the module substrate 90, the balun 20 that is disposed in the module substrate 90 and includes the primary coil 21 connected between an output end of the power amplifier 11 and an output end of the power amplifier 12 and the secondary coil 22 connected between the matching circuit 30 and the ground, the power supply terminals 61 and 62 that are disposed on the module substrate 90 and are switchably connected to the connection portion 213 between the end portions 211 and 212 of the primary coil 21, the switch circuit 40 that is disposed on the module substrate 90 and is connected between each of the power supply terminals 61 and 62 and the primary coil 21, and the power supply line 500 that is disposed on the module substrate 90 and electrically connects between the switch circuit 40 and the connection portion 213 of the primary coil 21. The module substrate 90 is divided into the regions 91 to 93 along a predetermined direction. The region 92 is located between the regions 91 and 93. The predetermined direction is the X direction perpendicular to the line segment 71 connecting the end portions 211 and 212 of the primary coil 21 in plan view of the module substrate 90. The balun 20 is disposed in the region 92 and is not disposed in the regions 91 and 93. The output terminal 403 of the switch circuit 40 is disposed in the region 93. The matching circuit 30 is disposed in the region 91 and is not disposed in the region 92.

According to another aspect, the radio frequency module 1 according to the present embodiment includes the module substrate 90, the integrated circuit 10 that is disposed on the module substrate 90 and includes the power amplifiers 11 and 12, the matching circuit 30 disposed on the module substrate 90, the balun 20 that is disposed in the module substrate 90 and includes the primary coil 21 connected between an output end of the power amplifier 11 and an output end of the power amplifier 12 and the secondary coil 22 connected between the matching circuit 30 and the ground, the power supply terminals 61 and 62 that are disposed on the module substrate 90 and are switchably connected to the connection portion 213 between the end portions 211 and 212 of the primary coil 21, the switch circuit 40 that is disposed on the module substrate 90 and is connected between each of the power supply terminals 61 and 62 and the primary coil 21, and the power supply line 500 that is disposed on the module substrate 90 and electrically connects between the switch circuit 40 and the connection portion 213 of the primary coil 21. In plan view of the module substrate 90, the distance DI between the power supply line 500 and the matching circuit 30 along a direction perpendicular to a predetermined direction is longer than the distance D2 between the power supply line 500 and a predetermined point on an outer edge of the balun 20 along the direction perpendicular to the predetermined direction. The direction perpendicular to the predetermined direction is the Y direction parallel to the line segment 71 connecting the end portions 211 and 212 of the primary coil 21. The predetermined point is the point 72 on the outer edge of the balun 20 farthest from a perpendicular bisector of the line segment 71.

With these configurations, the matching circuit 30 can be placed away from the connection portion 213 of the primary coil 21 and the output terminal 403 of the switch circuit 40 as compared with the case where the matching circuit 30 is disposed in the region 92 and the matching circuit 30 can be placed away from the power supply line 500. Accordingly, the leakage of noise from the power supply line 500 to the matching circuit 30 can be suppressed and the deterioration of characteristics of the radio frequency module 1 can be suppressed. In particular, even if noise flowing into the power supply line 500 is increased by the switch circuit 40 for switching between power supply voltages to be supplied to the differential amplifier (the power amplifiers 11 and 12), the coupling between the power supply line 500 and the matching circuit 30 can be suppressed and the deterioration of characteristics of the radio frequency module 1 can be effectively suppressed.

For example, in the radio frequency module 1 according to the present embodiment, the switch circuit 40 may be disposed in the region 93 and the balun 20 may be disposed between the matching circuit 30 and the switch circuit 40.

In this case where the switch circuit 40 is disposed in the region 93 and the balun 20 is interposed between the matching circuit 30 and the switch circuit 40, the matching circuit 30 can be placed away from the switch circuit 40 and the leakage of noise from the switch circuit 40 to the matching circuit 30 can be suppressed.

For example, in the radio frequency module 1 according to the present embodiment, the power supply terminals 61 and 62 may be disposed in the region 93.

For example, in the radio frequency module 1 according to the present embodiment, the power supply terminals 61 and 62 may at least partly overlap the switch circuit 40 in plan view of the module substrate 90.

In this case, the wiring line length between each of the power supply terminals 61 and 62 and the switch circuit 40 can be shortened and the effect of noise from a wiring line between each of the power supply terminals 61 and 62 and the switch circuit 40 can be suppressed.

For example, in the radio frequency module 1 according to the present embodiment, the end portion 221 of the secondary coil 22 connected to the matching circuit 30 may be located farthest from the region 93 of portions of the secondary coil 22.

In this case, the end portion 221 of the secondary coil 22 connected to the matching circuit 30 can be placed away from the switch circuit 40 and the leakage of noise from the switch circuit 40 to the matching circuit 30 can be suppressed.

For example, the radio frequency module 1 according to the present embodiment may further include the capacitor 52 that is disposed in the region 92 and is connected between the power supply line 500 and the ground.

In this case, noise on the power supply line 500 can be reduced.

For example, in the radio frequency module 1 according to the present embodiment, the primary coil 21 and the secondary coil 22 may be formed by a pattern wiring line of the module substrate 90.

In this case, the number of components in the radio frequency module 1 can be reduced.

For example, in the radio frequency module 1 according to the present embodiment, the secondary coil 22 may be formed in the multiple layers 902 and 903 of the module substrate 90.

In this case, the degree of freedom of disposition of the end portion 221 of the secondary coil 22 can be increased and the end portion 221 can be easily placed away from the switch circuit 40 as compared with the case where the secondary coil 22 is formed in a single layer. This is effective for noise reduction.

For example, the radio frequency module 1 according to the present embodiment may further include the metal wall 96 disposed between the matching circuit 30 and the switch circuit 40.

In this case, the coupling between the matching circuit 30 and the switch circuit 40 can be suppressed and the leakage of noise from the switch circuit 40 to the matching circuit 30 can be suppressed.

### Second Embodiment

Next, the second embodiment will be described. In the present embodiment, the disposition of the switch circuit 40 and the capacitor 52 differs mainly from the first embodiment. The present embodiment will be described in detail below with reference to the drawings, focusing on points different from the first embodiment.

The circuit configuration of a radio frequency module 1A according to the present embodiment is the same as that of the radio frequency module 1 according to first embodiment except that the inductor 51 is omitted, and the illustration and description thereof will therefore be omitted.

### 2.1 Installation Example of Radio Frequency Module 1A

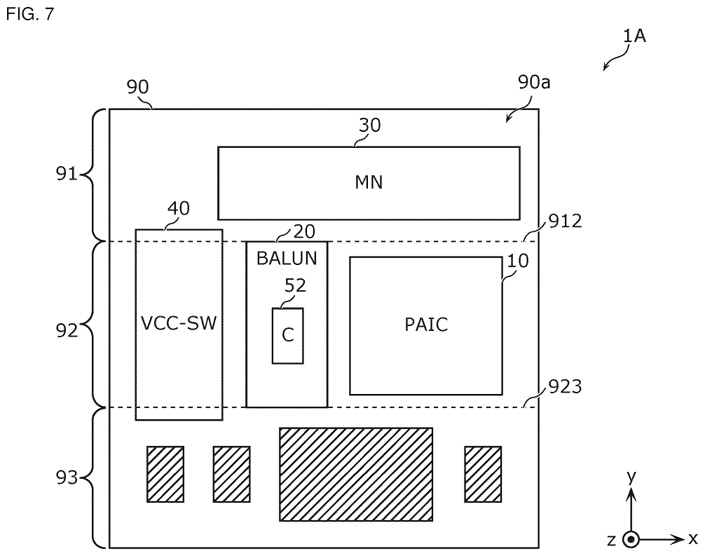

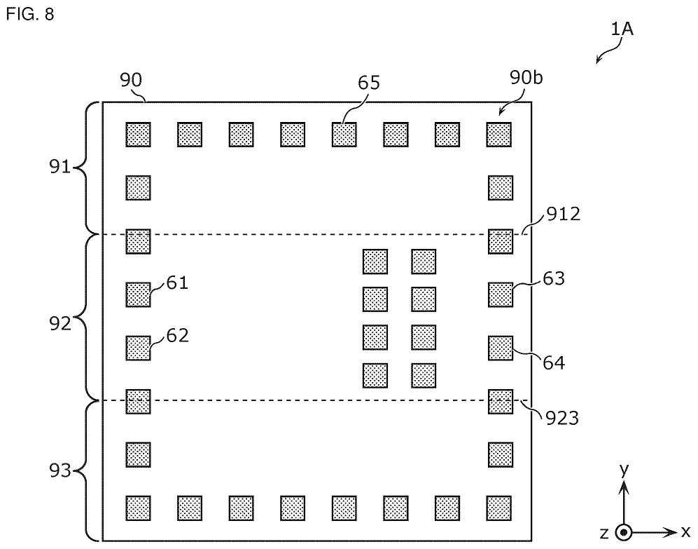

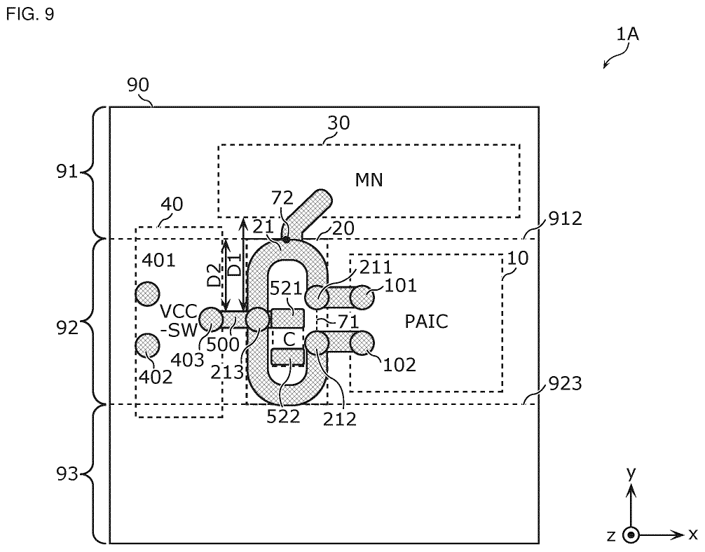

An installation example of the radio frequency module 1A according to the present embodiment will be described with reference to FIGS. 7 to 9. FIG. 7 is a plan view of the radio frequency module 1A according to the present embodiment. FIG. 8 is a plan view of the radio frequency module 1A according to the present embodiment, with the main surface 90b of the module substrate 90 viewed in perspective from the positive side of the Z axis. FIG. 9 is a wiring diagram of the radio frequency module 1A according to the present embodiment.

In FIGS. 7 and 9, some of components are marked with labels representing the components so that the arrangement relationship of the components can be easily understood, but actual components do not necessarily have to be marked with such labels. In FIG. 7, the illustration of the resin member 94 covering a plurality of circuit components and the shield electrode layer 95 covering the surface of the resin member 94 is omitted. In FIG. 7, optional circuit components that are not essential in the present disclosure are hatched.

FIGS. 7 to 9 illustrate an installation example of the radio frequency module 1A, and the radio frequency module 1A can be installed using any of various installations and circuit techniques. Accordingly, the following description of the radio frequency module 1A should not be interpreted in a limited manner.

The switch circuit 40 is disposed in the regions 91 to 93 of the module substrate 90 and is disposed mainly in the region 92. In the present embodiment, the input terminals 401 and 402 and the output terminal 403 of the switch circuit 40 are disposed in the region 92 of the module substrate 90 and are not disposed in the regions 91 and 93 of the module substrate 90. The balun 20 is disposed between the integrated circuit 10 and the switch circuit 40.

The power supply terminals 61 and 62 are disposed in the region 92 of the module substrate 90 and at least partly overlaps the switch circuit 40 in plan view of the module substrate 90.

The capacitor 52 is disposed in the region 92 of the module substrate 90 and is disposed inside the primary coil 21 and the secondary coil 22 in plan view of the module substrate 90.

As illustrated in FIG. 9, also in the present embodiment, the distance D1 (an example of the first distance) between the power supply line 500 and the matching circuit 30 along the Y direction is longer than the distance D2 (an example of the second distance) between the power supply line 500 and the point 72 on the outer edge of the balun 20 along the Y direction in plan view of the module substrate 90 like in the first embodiment.

The radio frequency module 1A does not include the metal wall 96 in the present embodiment, but may include the metal wall 96 disposed between the matching circuit 30 and the switch circuit 40 like in the first embodiment.

### 2.2 Effects, Etc.

As described above, the radio frequency module 1A according to the present embodiment includes the module substrate 90, the integrated circuit 10 that is disposed on the module substrate 90 and includes the power amplifiers 11 and 12, the matching circuit 30 disposed on the module substrate 90, the balun 20 that is disposed in the module substrate 90 and includes the primary coil 21 connected between an output end of the power amplifier 11 and an output end of the power amplifier 12 and the secondary coil 22 connected between the matching circuit 30 and the ground, the power supply terminals 61 and 62 that are disposed on the module substrate 90 and are switchably connected to the connection portion 213 between the end portions 211 and 212 of the primary coil 21, the switch circuit 40 that is disposed on the module substrate 90 and is connected between each of the power supply terminals 61 and 62 and the primary coil 21, and the power supply line 500 that is disposed on the module substrate 90 and electrically connects between the output terminal 403 of the switch circuit 40 and the connection portion 213 of the primary coil 21. The module substrate 90 is divided into the regions 91 to 93 along a predetermined direction. The region 92 is located between the regions 91 and 93. The predetermined direction is the X direction perpendicular to the line segment 71 connecting the end portions 211 and 212 of the primary coil 21 in plan view of the module substrate 90. The balun 20 is disposed in the region 92 and is not disposed in the regions 91 and 93. The output terminal 403 of the switch circuit 40 is disposed in the region 92. The matching circuit 30 is disposed in the region 91 and is not disposed in the region 92.

According to another aspect, the radio frequency module 1A according to the present embodiment includes the module substrate 90, the integrated circuit 10 that is disposed on the module substrate 90 and includes the power amplifiers 11 and 12, the matching circuit 30 disposed on the module substrate 90, the balun 20 that is disposed in the module substrate 90 and includes the primary coil 21 connected between an output end of the power amplifier 11 and an output end of the power amplifier 12 and the secondary coil 22 connected between the matching circuit 30 and the ground, the power supply terminals 61 and 62 that are disposed on the module substrate 90 and are switchably connected to the connection portion 213 between the end portions 211 and 212 of the primary coil 21, the switch circuit 40 that is disposed on the module substrate 90 and is connected between each of the power supply terminals 61 and 62 and the primary coil 21, and the power supply line 500 that is disposed on the module substrate 90 and electrically connects between the switch circuit 40 and the connection portion 213 of the primary coil 21. In plan view of the module substrate 90, the distance D1 between the power supply line 500 and the matching circuit 30 along a direction perpendicular to a predetermined direction is longer than the distance D2 between the power supply line 500 and a predetermined point on an outer edge of the balun 20 along the direction perpendicular to the predetermined direction. The direction perpendicular to the predetermined direction is the Y direction parallel to the line segment 71 connecting the end portions 211 and 212 of the primary coil 21. The predetermined point is the point 72 on the outer edge of the balun 20 farthest from a perpendicular bisector of the line segment 71.

With these configurations, the matching circuit 30 can be placed away from the connection portion 213 of the primary coil 21 and the output terminal 403 of the switch circuit 40 as compared with the case where the matching circuit 30 is disposed in the region 92 and the matching circuit 30 can be placed away from the power supply line 500. Accordingly, the leakage of noise from the power supply line 500 to the matching circuit 30 can be suppressed and the deterioration of characteristics of the radio frequency module 1 can be suppressed. In particular, even if noise flowing into the power supply line 500 is increased by the switch circuit 40 for switching between power supply voltages to be supplied to the differential amplifier (the power amplifiers 11 and 12), the coupling between the power supply line 500 and the matching circuit 30 can be suppressed and the deterioration of characteristics of the radio frequency module 1A can be effectively suppressed.

For example, in the radio frequency module 1A according to the present embodiment, the switch circuit 40 may be disposed in the region 92 and the balun 20 may be disposed between the integrated circuit 10 and the switch circuit 40.

In this case, the switch circuit 40 is disposed in the region 92 and the balun 20 is disposed between the integrated circuit 10 and the switch circuit 40. As a result, the power supply line 500 between the switch circuit 40 and the connection portion 213 located on the opposite side of the end portions 221 and 222 of the primary coil 21 can be shortened and the effect of noise from the power supply line 500 can be suppressed.

For example, in the radio frequency module 1A according to the present embodiment, the power supply terminals 61 and 62 may be disposed in the second region 92.

For example, in the radio frequency module 1A according to the present embodiment, the power supply terminals 61 and 62 may at least partly overlap the switch circuit 40 in plan view of the module substrate 90.

In this case, the wiring line length between each of the power supply terminals 61 and 62 and the switch circuit 40 can be shortened and the effect of noise from a wiring line between each of the power supply terminals 61 and 62 and the switch circuit 40 can be suppressed.

For example, the radio frequency module 1A according to the present embodiment may further include the capacitor 52 that is disposed in the region 92 and is connected between the power supply line 500 and the ground.

In this case, noise on the power supply line 500 can be reduced.

For example, in the radio frequency module 1A according to the present embodiment, the capacitor 52 may be disposed inside the primary coil 21 and the secondary coil 22 in plan view of the module substrate 90.

In this case, the power supply line 500 between the switch circuit 40 and the balun 20 can be shortened because there is no need to dispose the capacitor 52 between the switch circuit 40 and the balun 20.

For example, in the radio frequency module 1A according to the present embodiment, the primary coil 21 and the secondary coil 22 may be formed by a pattern wiring line of the module substrate 90.

In this case, the number of components in the radio frequency module 1A can be reduced.

For example, in the radio frequency module 1A according to the present embodiment, the secondary coil 22 may be formed in the multiple layers 902 and 903 of the module substrate 90.

In this case, the degree of freedom of disposition of the end portion 221 of the secondary coil 22 can be increased and the end portion 221 can be easily placed away from the switch circuit 40 as compared with the case where the secondary coil 22 is formed in a single layer. This is effective for noise reduction.

### Other Embodiments

The description of a radio frequency module according to the present disclosure has been made with the embodiments, but a radio frequency module according to the present disclosure is not limited to the above embodiments. The present disclosure also includes other embodiments realized by combining optional constituent elements in the above embodiments, modifications obtained by making various changes, which are conceived by those skilled in the art, to the above embodiments without departing from the spirit and scope of the present disclosure, and various devices including the above radio frequency module.

For example, in the circuit configuration of a radio frequency module according to each of the above embodiments, another circuit element and another wiring line may be inserted between each of the circuit elements and the path connecting the signal paths, which are illustrated in the drawings. For example, a filter may be inserted between the matching circuit 30 and the antenna connection terminal 65.

The balun 20 is formed by a pattern wiring line of the module substrate 90 in each of the above embodiments, but the formation of the balun 20 is not limited thereto. For example, the balun 20 may be formed by an SMD.

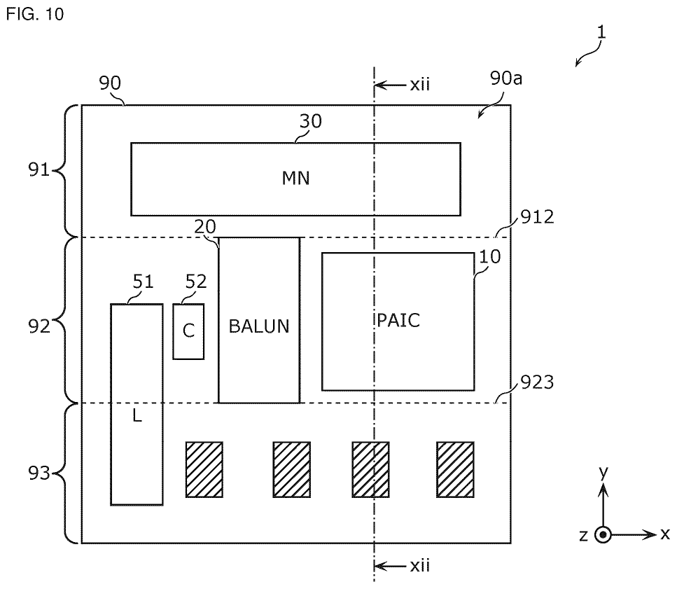

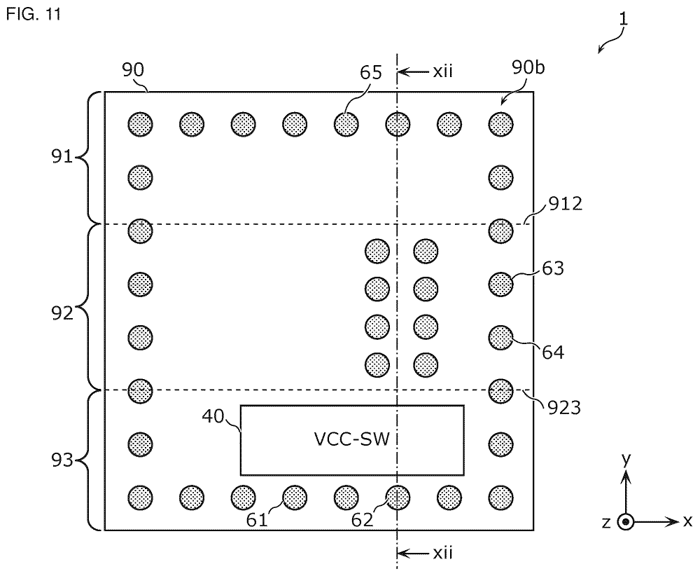

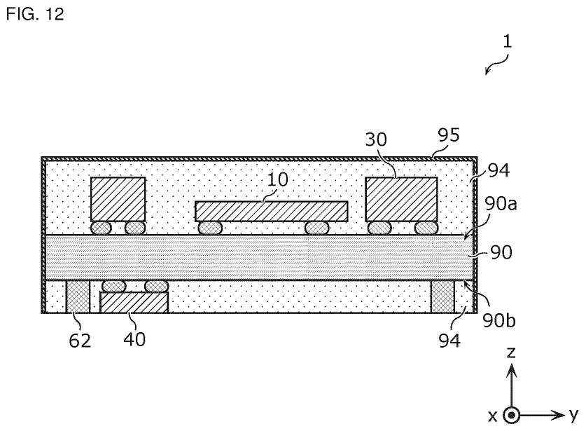

The circuit components of the radio frequency module are disposed on the main surface 90a that is one of the main surfaces of the module substrate 90 in the above embodiments, but may be disposed on the main surfaces 90a and 90b which are both of the main surfaces. For example, the matching circuit 30 may be disposed on the main surface 90a and the switch circuit 40 may be disposed on the main surface 90b in the radio frequency module 1 as illustrated in FIGS. 10 to 12. In this case, the coupling between the matching circuit 30 and the switch circuit 40 can be suppressed and the leakage of noise from the switch circuit 40 to the matching circuit 30 can be suppressed. For example, in addition to the switch circuit 40, the power supply line 500 and the capacitor 52 may also be disposed on the main surface 90b. In this case, the degree of freedom of disposition of the switch circuit 40, the power supply line 500, and the capacitor 52 can be improved and, for example, the switch circuit 40 can be disposed on the main surface 90b to at least partly overlap the balun 20 in plan view of the module substrate 90. As a result, the length of the power supply line 500 can be shortened and the effect of noise from the power supply line 500 can be suppressed. The matching circuit 30 disposed on the main surface 90a can be placed away from the power supply line 500 and the leakage of noise from the power supply line 500 to the matching circuit 30 can be further suppressed.

The features of a radio frequency module described on the basis of the above embodiments will be described below.
<1>

A radio frequency module comprising:
a module substrate;
an integrated circuit that is disposed on the module substrate and includes a first power amplifier and a second power amplifier;
a matching circuit disposed on the module substrate;
a balun that is disposed in the module substrate and includes a primary coil connected between an output end of the first power amplifier and an output end of the second power amplifier and a secondary coil connected between the matching circuit and a ground;
a first power supply terminal and a second power supply terminal that are disposed on the module substrate and are switchably connected to a connection portion between both end portions of the primary coil;
a switch circuit that is disposed on the module substrate and is connected between each of the first power supply terminal and the second power supply terminal and the primary coil; and
a power supply line that is disposed on the module substrate and electrically connects between the switch circuit and the connection portion of the primary coil,
wherein, in plan view of the module substrate, a first distance between the power supply line and the matching circuit along a direction perpendicular to a predetermined direction is longer than a second distance between the power supply line and a predetermined point on an outer edge of the balun along the direction perpendicular to the predetermined direction,
wherein the direction perpendicular to the predetermined direction is parallel to a line segment connecting the both end portions of the primary coil, and
wherein the predetermined point is a point on the outer edge of the balun farthest from a perpendicular bisector of the line segment.
<2>

The radio frequency module according to <1>, wherein the balun is disposed between the matching circuit and the switch circuit.
<3>

The radio frequency module according to <1>, wherein the balun is disposed between the integrated circuit and the switch circuit.
<4>

The radio frequency module according to any one of <1> to <3>, wherein each of the first power supply terminal and the second power supply terminal at least partly overlaps the switch circuit in plan view of the module substrate.
<5>

The radio frequency module according to any one of <1> to <4>, further comprising a capacitor that is disposed on the module substrate and is connected between the power supply line and the ground.
<6>

The radio frequency module according to <5>, wherein the capacitor is disposed inside the primary coil and the secondary coil in plan view of the module substrate.
<7>

The radio frequency module according to any one of <1> to <6>, wherein the primary coil and the secondary coil are formed by a pattern wiring line of the module substrate.
<8>

The radio frequency module according to <7>, wherein the secondary coil is formed in a plurality of layers of the module substrate.
<9>

The radio frequency module according to any one of <1> to <8>, further comprising a metal wall disposed between the matching circuit and the switch circuit.
<10>

The radio frequency module according to any one of <1> to <9>,
wherein the module substrate has a first main surface and a second main surface facing each other,
wherein the matching circuit is disposed on the first main surface, and
wherein the switch circuit is disposed on the second main surface.
<11>

A radio frequency module comprising:
a module substrate;
an integrated circuit that is disposed on the module substrate and includes a first power amplifier and a second power amplifier;
a matching circuit disposed on the module substrate;
a balun that is disposed in the module substrate and includes a primary coil connected between an output end of the first power amplifier and an output end of the second power amplifier and a secondary coil connected between the matching circuit and a ground;
a first power supply terminal and a second power supply terminal that are disposed on the module substrate and are switchably connected to a connection portion between both end portions of the primary coil;
a switch circuit that is disposed on the module substrate and is connected between each of the first power supply terminal and the second power supply terminal and the primary coil; and
a power supply line that is disposed on the module substrate and electrically connects between an output terminal of the switch circuit and the connection portion of the primary coil,
wherein the module substrate is divided into a first region, a second region, and a third region along a predetermined direction, and the second region is located between the first region and the third region,
wherein the predetermined direction is perpendicular to a line segment connecting the both end portions of the primary coil in plan view of the module substrate,
wherein the balun is disposed in the second region and is not disposed in the first region and the third region,
wherein the output terminal of the switch circuit is disposed in the second region or the third region, and
wherein the matching circuit is disposed in the first region and is not disposed in the second region.
<12>

The radio frequency module according to <11>,
wherein the switch circuit is disposed in the third region, and
wherein the balun is disposed between the matching circuit and the switch circuit.
<13>

The radio frequency module according to <12>, wherein the first power supply terminal and the second power supply terminal are disposed in the third region.
<14>

The radio frequency module according to <11>, wherein the switch circuit is disposed in the second region, and wherein the balun is disposed between the integrated circuit and the switch circuit.
<15>

The radio frequency module according to <14>, wherein the first power supply terminal and the second power supply terminal are disposed in the second region.
<16>

The radio frequency module according to any one of <11> to <15>, wherein an end portion of the secondary coil which is connected to the matching circuit is located farthest from the third region of portions of the secondary coil.
<17>

The radio frequency module according to any one of <11> to <16>, further comprising a capacitor that is disposed in the second region and is connected between the power supply line and the ground.
<18>

The radio frequency module according to <17>, wherein the capacitor is disposed inside the primary coil and the secondary coil in plan view of the module substrate.
<19>

The radio frequency module according to any one of <11> to <18>, wherein the primary coil and the secondary coil are formed by a pattern wiring line of the module substrate.
<20>

The radio frequency module according to <19>, wherein the secondary coil is formed in a plurality of layers of the module substrate.

The present disclosure is widely applicable for use in a communication device such as a cellular phone as a radio frequency module disposed in a front-end portion.

What is claimed is:

1. A radio frequency module comprising:
a module substrate;
an integrated circuit that is disposed on the module substrate, the integrated circuit including a first power amplifier and a second power amplifier;
a matching circuit disposed on the module substrate;
a balun that is disposed on the module substrate, wherein the balun includes a primary coil and a secondary coil, the primary coil is connected between an output end of the first power amplifier and an output end of the second power amplifier, and the secondary coil is connected between the matching circuit and a ground;
a first power supply terminal and a second power supply terminal that are disposed on the module substrate and are switchably connected to a connector between both ends of the primary coil;
a switch circuit that is disposed on the module substrate and is connected between each of the first power supply terminal, the second power supply terminal and the primary coil; and
a power supply line that is disposed on the module substrate and is electrically connected between the switch circuit and the connector of the primary coil, wherein
in a plan view of the module substrate, a first distance is longer than a second distance,
the first distance being between the power supply line and the matching circuit along a direction parallel to a line segment connecting both ends of the primary coil,
the second distance is between the power supply line and a predetermined point on an outer edge of the balun along the direction, and
the predetermined point is on the outer edge of the balun farthest from a perpendicular bisector of the line segment.

2. The radio frequency module according to claim 1, wherein the balun is disposed between the matching circuit and the switch circuit.

3. The radio frequency module according to claim 1, wherein the balun is disposed between the integrated circuit and the switch circuit.

4. The radio frequency module according to claim 1, wherein each of the first power supply terminal and the second power supply terminal at least partly overlaps the switch circuit in the plan view of the module substrate.

5. The radio frequency module according to claim 1, further comprising a capacitor that is disposed on the module substrate and is connected between the power supply line and the ground.

6. The radio frequency module according to claim 5, wherein the capacitor is disposed inside the primary coil and the secondary coil in the plan view of the module substrate.

7. The radio frequency module according to claim 1, wherein the primary coil and the secondary coil are formed by a pattern wiring line of the module substrate.

8. The radio frequency module according to claim 7, wherein the secondary coil is formed in a plurality of layers of the module substrate.

9. The radio frequency module according to claim 1, further comprising a metal wall disposed between the matching circuit and the switch circuit.

10. The radio frequency module according to claim 1, wherein
the module substrate has a first main surface and a second main surface facing each other,
the matching circuit is disposed on the first main surface, and
the switch circuit is disposed on the second main surface.

11. A radio frequency module comprising:
a module substrate;
an integrated circuit that is disposed on the module substrate, the integrated circuit including a first power amplifier and a second power amplifier;
a matching circuit disposed on the module substrate;
a balun that is disposed in the module substrate, wherein the balun includes a primary coil and a secondary coil, the primary coil is connected between an output end of the first power amplifier and an output end of the second power amplifier, and the secondary coil is connected between the matching circuit and a ground;
a first power supply terminal and a second power supply terminal that are disposed on the module substrate and are switchably connected to a connector between both ends of the primary coil;
a switch circuit that is disposed on the module substrate and is connected between each of the first power supply terminal, the second power supply terminal and the primary coil; and
a power supply line that is disposed on the module substrate and is electrically connected between an output terminal of the switch circuit and the connector of the primary coil, wherein
the module substrate is divided into a first region, a second region, and a third region along a predetermined direction,
the second region is located between the first region and the third region,
the predetermined direction is perpendicular to a line segment connecting the both ends of the primary coil in a plan view of the module substrate,
the balun is disposed in only the second region,
the output terminal of the switch circuit is disposed in the second region or the third region, and
the matching circuit is disposed in only the first region.

12. The radio frequency module according to claim 11, wherein
the switch circuit is disposed in the third region, and
the balun is disposed between the matching circuit and the switch circuit.

13. The radio frequency module according to claim 12, wherein the first power supply terminal and the second power supply terminal are disposed in the third region.

14. The radio frequency module according to claim 11, wherein
the switch circuit is disposed in the second region, and
the balun is disposed between the integrated circuit and the switch circuit.

15. The radio frequency module according to claim 14, wherein the first power supply terminal and the second power supply terminal are disposed in the second region.

16. The radio frequency module according to claim 11, wherein an end of the secondary coil which is connected to the matching circuit is located farthest from the third region of portions of the secondary coil.

17. The radio frequency module according to claim 11, further comprising a capacitor that is disposed in the second region and is connected between the power supply line and the ground.

18. The radio frequency module according to claim 17, wherein the capacitor is disposed inside the primary coil and the secondary coil in the plan view of the module substrate.

19. The radio frequency module according to claim 11, wherein the primary coil and the secondary coil are formed by a pattern wiring line of the module substrateI.

20. A radio frequency module comprising:
a module substrate;
an integrated circuit that is disposed on the module substrate, the integrated circuit including a first power amplifier and a second power amplifier;
a matching circuit disposed on the module substrate;
a balun that is disposed on the module substrate, wherein the balun and includes a primary coil and a secondary coil, the primary coil is connected between an output end of the first power amplifier and an output end of the second power amplifier, and the secondary coil is connected between the matching circuit and a ground;
a first power supply terminal and a second power supply terminal that are disposed on the module substrate and are switchably connected to a connector between both ends of the primary coil;
a switch circuit that is disposed on the module substrate and is connected between each of the first power supply terminal, the second power supply terminal and the primary coil; and
a power supply line that is disposed on the module substrate and is electrically connected between the switch circuit and the connector of the primary coil, wherein
in a plan view of the module substrate, a first distance is longer than a second distance, and the power supply line includes a portion extending from the connector in a direction perpendicular to a line segment connecting both ends of the primary coil,
the first distance is along a direction parallel to the line segment and is between the portion and the matching circuit,
the second distance is along the direction parallel to the line segment and is between the power supply line and a predetermined point on an outer edge of the balun, and
the predetermined point is a point on the outer edge of the balun farthest from a perpendicular bisector of the line segment.
